(19) United States
(12) Patent Application Publication
(10) Pub. No.: US 2020/0105154 A1
(43) Pub. Date: Apr. 2, 2020

(54) PROVIDING BROAD ACCESS TO MICRO- AND NANO-SCALE TECHNOLOGIES

(71) Applicant: Board of Regents, The University of Texas System, Austin, TX (US)

(72) Inventors: Sidlgata V. Sreenivasan, Austin, TX (US); Ovadia Abed, Austin, TX (US); Lawrence R. Dunn, Austin, TX (US); Aseem Sayal, Austin, TX (US); Shrawan Singhal, Austin, TX (US)

(21) Appl. No.: 16/613,866

(22) PCT Filed: May 16, 2018
(86) PCT No.: PCT/US2018/032890

§ 371 Date: Nov. 15, 2019

Related U.S. Application Data
(60) Provisional application No. 62/506,684, filed on May 16, 2017.

(51) Int. Cl. G09B 5/00; G06F 30/10

(52) U.S. Cl. CPC G09B 5/00; G09B 7/00; G06F 30/10

(57) ABSTRACT

A portable system to enable broad access to micro- and nano-scale technologies. The portable system includes a fabrication module configured to enable creation of a small tech device or structure or to enable demonstration of a small tech process. The portable system further includes a metrology module configured to allow measuring, testing or characterizing a property of the small tech device, structure or process. Furthermore, the portable system includes a quality control module configured to validate results from the metrology module against a set of expected results measured independently. The portable system is used for the design and assembly of a prototype tool with all the functionalities or a subset of functionalities present in a master tool used in a small tech factory.

### CROSS REFERENCE TO RELATED APPLICATIONS

This application claims priority to U.S. Provisional Patent Application Ser. No. 62/506,684, entitled “Providing Broad Access to Micro- and Nano-Scale Technologies,” filed May 16, 2017, which is incorporated by reference herein in its entirety.

### GOVERNMENT INTERESTS

This invention was made with government support under Grant No. ECCS1120823 and Grant No. IIP1514640 awarded by the National Science Foundation. The U.S. government has certain rights in the invention.

### TECHNICAL FIELD

The present invention relates generally to micro- and nano-scale technologies, and more particularly to a portable education system for providing broad access to micro- and nano-scale technologies.

### BACKGROUND

Miniaturization, or “small tech,” has revolutionized the world we live in today. It has transformed computers from gigantic rooms to the size of our palms, changed displays from being too bulky to carry to being wrappable like a plastic sheet and allowed sensors to be ubiquitously present in our everyday lives, to name a few. This miniaturization has been made possible because of our ability to fabricate multi-scale devices: human-scale devices (on the order of a square millimeter in cross-section area or greater, or a cubic millimeter volume or greater) with controlled minimum features that provide functionality at scales that are much smaller possessing minimum functional feature size (MIFFS) on the order of hundreds of micrometers or significantly smaller. The semiconductor fabrication industry has led this trend with the self-prophetic Moore's Law. Driven by aggressive scaling of lithography, it allowed fabrication of smaller transistors along with the ability to pack more transistors in the same form factor. The MIFFS has gone from 100 micrometers, to 10 micrometers, then to 1 micrometer and more recently, well below 100 nanometers. This continuous shrinking trend has led to tremendous increases in useful functionality in a broad spectrum of applications including computing (e.g., data storage, displays, sensors and controllers in automotive, aerospace, defense and security), healthcare monitoring, pharmaceuticals, gaming and entertainment, energy generation and storage, etc. For example, in computing, power (processing speed and complexity), reduced power consumption, low power ultra-high density memory, and high-resolution low power displays, all available in compact form factors, have led to the revolution in mobile computing.

There are other major industries enabled by specialty small tech materials with morphological control at the micro- or nano-scales. This includes micro- and nano-scale controlled particles (e.g., polystyrene spheres, gold nanoparticles, etc.); specialty carbon based materials, such as fullerenes, carbon nanotubes, nanowires, etc.; two-dimensional materials, such as graphene, molybdenum disulfide, etc.; organic electronic materials, such as polythiophene; and other solid state nanomaterials, such as semiconducting nanowires, nanotubes, etc.

These small tech devices and materials have become broadly accessible to society as the benefit of this technological intervention has penetrated all aspects of our lives. While more and more people are using small tech, it has, however, become increasingly difficult for the broad population to be involved in making, characterizing, understanding and designing these technologies. For example, the number of commercial companies owning fabrication facilities that make semiconductor chips or flat panel displays has shrunk tremendously in the last few decades as the factories have become increasingly more complicated. There are a few trends that are leading to the exclusion of the broader population from the creation of these advanced technologies.

For example, as millions or billions of functional components are now contained in the human-scale devices, carrying out the fabrication processes with a profitable yield has become a challenge because of the presence of airborne particles and contaminants in the room air. Normal room air can have a large number of particles ranging from 10-1,000 micrometers in size. However, as fabrication resolution has approached these sizes, and then become substantially smaller than these sizes, it has become imperative to execute the processes in expensive dedicated facilities called cleanrooms, which continuously filter the ambient environment to get rid of a large number of particles above a given size. At this transition of fabrication resolution, while the benefits associated with continued miniaturization continued to increase, the ability to fabricate relevant structures and devices transformed from broadly accessible shops to sophisticated fabrication facilities or “fabs.”

Another trend is the need for highly sophisticated equipment to be placed in the factories. Such equipment is based on the understanding of complex multi-scale phenomena, and is computer controlled and automated. These expensive machines are needed to execute manufacturing or measurement tasks that can accurately address all the millions (or billions) of functional sub-components over a human-scale device with low error rates. The cost and complexity of operation of this equipment is a barrier for broad access even in non-cleanroom environments. This barrier can be further aggravated if these types of equipment may be additionally placed in cleanroom-based fabs.

A further trend is that the nature of chemicals and materials required to effectively perform the manufacturing tasks have become increasingly sophisticated, specialized, and expensive. Synthesizing small tech materials and producing them at scale with adequate quality requires significant investment, know-how and a critical mass of skilled labor. Materials with undesirable contamination levels of less than parts per million going to parts per billion and even parts per trillion, are now available. These specialized materials may also be toxic to humans (for example, gases such as chlorine, used in semiconductor fabrication), and need very specialized handling protocols and/or automation for human safety.

Another trend is the scaling down to small tech that has also led to challenges in (i) understanding the benefits of small tech in multi-scale devices, (ii) exploiting this extreme complexity for novel device designs, and (iii) characterization and testing of these complicated devices after fabrication to ensure that they perform as expected. In another twist, as resolution has continued to scale further down into the sub-micrometer range, it has become apparent that the physical, chemical and biological phenomena observed at millimeter- and micrometer-scales are no longer necessarily applicable. For example, sub-wavelength optical phenomena at scales that are a fraction of the wavelength of light has led to diffractive optics, photonic crystals, plasmonics, and novel metamaterials; magnetic materials demonstrate unusual instabilities below their “superparamagnetic material limits”; spin-transfer-torque based magnetic memory devices have been demonstrated; nanoparticle bio-carriers have been developed to enhance the efficacy and targeting of diagnostic and drug agents by exploiting bio-distribution mechanisms and cell uptake mechanisms that are unique at sub-micrometer scales; and novel energy storage devices have been developed using nanowires and nanotubular structures. Since these phenomena are unusual and distinct from human-scale behavior, they become broadly inaccessible unless making, characterizing, understanding and designing of these devices is broadly accessible. Fabrication at these scales not only require highly specialized equipment, materials and facilities, but also requires metrology tools capable of detecting seemingly anomalous behavior at these scales.

Within the domain of small tech, the United States of America and other nations have identified nanotechnology as a research and technology area of particular strategic importance. The National Science Foundation defines nanotechnology as “research and technology development at the atomic, molecular or macromolecular levels . . . to provide a fundamental understanding of phenomena and materials at the nanoscale and to create and use structures, devices and systems that have novel properties and functions because of their small and/or intermediate size . . . ” In recent years, the impact of nanotechnology on societally useful applications and products has increased quite dramatically. Upon comparison with earlier technologies, such as electricity, televisions, etc., that have now penetrated nearly all developed countries' households, it can be seen that the growth trend of nanotechnology-related interventions is commensurate with increasingly rapid adoption in the near future.

However, all the exciting developments in micro- and nano-scale technologies can be limited in many ways if the broader society is not empowered to participate in the value created by these technologies in our daily lives. In particular, lack of broad access to small tech can lead to two important challenges. The first challenge involves education. Lack of education and information about small tech, unfortunately, can lead to a limited and under-prepared workforce. Hence, it is imperative that small tech education also matches pace with the penetration of such technologies into broad societal applications. However, small tech education presents a substantial challenge on multiple fronts. Firstly, if one is interested in acquiring hands-on experience in the practice of small tech, it would often require extremely expensive infrastructure, in the form of cleanroom labs, or costly equipment, or specialized materials, or sophisticated device characterization and design, skilled personnel, etc. Within academia, this type of infrastructure is often confined to large research universities, and most often, to an even smaller group within these universities. This leaves a vast majority of people without access to practical small tech for education. Secondly, small tech is not a single classical discipline in and of itself, but cuts across all major STEM (science, technology, engineering and mathematics) disciplines. Most formal college education structures are not adaptive enough to handle such a broad curriculum, particularly at the associate and undergraduate levels, and even perhaps at the graduate level. Thirdly, many educators themselves are also not abreast of the fundamental advances taking place in the world of small tech because of its rather recent origins, rapid growth and its lack of classical STEM character. They are thus unable to offer classes in this area and also may not be able to inspire their students towards taking small tech seriously. Hence, it is important that these challenges are addressed for small tech education.

Another challenge is innovation. Lack of access to small tech for “making, characterizing, understanding and designing of multi-scale devices” can stifle innovation. Today, broad access to software education and development capabilities facilitates a number of products that are created every day by individuals, or companies (small, mid-size and large) to enhance our lives (e.g., smart phone “apps”). The innovation ecosystem for small tech devices and materials is significantly more constrained due to the lack of broad access to small tech infrastructure as previously discussed. There are some models that have succeeded in addressing this highly constrained infrastructure in specific areas; for example, the concept of “fab foundries” pioneered by foundry companies, such as Taiwan Semiconductors Manufacturing Corporation (TSMC). Foundries allow designers of application-specific integrated circuits (ASICs) to innovate by using standardized device design and analysis software. These companies then aggregate large numbers of such innovators to create the volume needed to justify the high expense of the foundry fab, and manufactures the ASIC devices for the third party innovators. While this model is highly successfully, it is still confined to the small niche area of Silicon CMOS Integrated Circuits with a highly constrained set of material and device types.

Unfortunately, there is not currently a means for providing broad access to micro- and nano-scale technologies.

### SUMMARY

In one embodiment of the present invention, a portable system comprises a fabrication module configured to enable creation of a small tech device or structure or to enable demonstration of a small tech process. The portable system further comprises a metrology module configured to allow measuring, testing or characterizing a property of the small tech device, structure or process. The portable system additionally comprises a quality control module configured to validate results from the metrology module against a set of expected results measured independently. The portable system is used for the design and assembly of a prototype tool with all the functionalities or a subset of functionalities present in a master tool used in a small tech factory.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates a small tech experimentation system (STES) (also referred to as a “portable education system”) in accordance with an embodiment of the present invention; and

FIG. 2 is a diagram of the sensing and safety control methodology for hand-held lab kits in accordance with an embodiment of the present invention.

### DETAILED DESCRIPTION

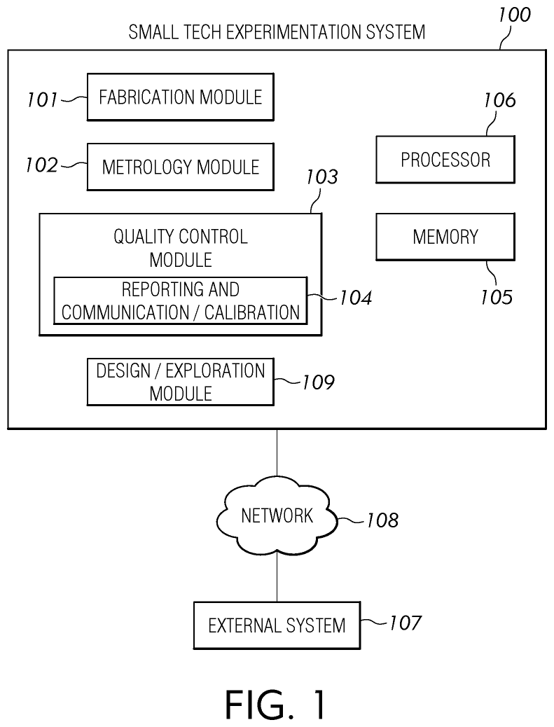

To address the challenge of broad access in small tech education and innovation discussed in the Background section, the present invention designs a small tech experimentation system (STES) (also referred to as a “portable education system”) 100 as shown in FIG. 1 in accordance with an embodiment of the present invention. In one embodiment, STES 100 is used for educational or training purposes. In one embodiment, STES 100 is a portable system with a dimension not exceeding 50 inches and with a weight not exceeding 25 pounds. Furthermore, STES 100 may be utilized in a household setting. Furthermore, STES 100 may be included as a part of an educational degree program or certificate program offered by an institution of higher learning or by a corporation, allowing broad access of small tech experimental education credentials to remote students. In one embodiment, STES 100 enables optical phenomena, magnetic phenomena, electronic phenomena, electrical phenomena, biological phenomena, thermal phenomena, chemical phenomena, and/or mechanical phenomena. In one embodiment, STES 100 enables micro-scale thin film deposition, nano-scale thin film deposition, micro-scale etching, nano-scale patterning, micro-scale patterning, and/or nano-scale etching. In one embodiment, STES 100 enables growth of micro-scale structures, and/or growth of nano-scale structures. In one embodiment, procedural instructions may accompany STES 100 directed to small tech fabrication safety, small tech metrology safety and/or small tech characterization safety. Furthermore, STES 100 enables experiments related to displays, experiments related to flexible electronics, experiments related to pharmaceutical, experiments related to medical diagnostics, experiments related to energy generation, experiments related to energy storage, experiments related to light emitting devices, experiments related to electronic devices, experiments related to demonstration of small tech fabrication processes and/or experiments related to fabrication of small tech structures. Experiments using STES 100 may be customized or randomized to allow creation of small tech devices or structures or execution of small tech processes across a group of systems. In one embodiment, experiments using STES 100 involve creation of small tech devices or structures or execution of small tech processes starting from a provided device or structure which is partially fabricated. In one embodiment, the partially-fabricated provided device or structure is substantially identical with a device or structure provided with another portable system. In one embodiment, the substantially identical device or structure is fabricated via multiple steps completed by multiple students, or by multiple students and a small tech factory. In one embodiment, the partially-fabricated provided device or structure is substantially identical but partially fabricated to a different extent when compared to a device or structure provided with another portable system. In one embodiment, STES 100 is substantially similar to a tool used in a small tech factory for executing a small tech process or for fabricating, measuring or characterizing a small tech device or structure. In one embodiment, STES 100 is partially similar to a tool used in a small tech factory executing a small tech process or for fabricating, measuring or characterizing a small tech device or structure. In one embodiment, the difference in functionality between STES 100 and a similar tool in a small tech factory is optimized or compensated using software programs, multimedia interactions, mixed reality tools, augmented reality tools or virtual reality tools.

Referring to FIG. 1, STES 100 includes a fabrication module 101 with a unique identifier that may enable creating a functioning multi-scale small tech device or features associated with such a device, with MFFS in the small tech regime over human-scale areas, where one or more characteristics of the devices can be varied in a controlled manner between different embodiments of the fabrication module. In one embodiment, fabrication module 101 is configured to enable the creation of a small tech device or structure or enable demonstration of a small tech process. Furthermore, fabrication module 101 may enable executing a small tech process with constituents that may include those that are pre-fabricated in the small tech factory with high precision and accuracy to make small tech structures or devices, where one or more characteristics of the constituents can be varied in a controlled manner between different embodiments of the fabrication module. Additionally, fabrication module 101 may enable the assembling of a prototype of a piece of equipment typically used for small tech processes. The prototype equipment (designed and assembled by STES 100) may retain substantially similar functionality (or the same functionality) of the “master” equipment typically used in a small tech factory. Any differences in functionality can be optimized for the allowable form factor, weight or household safety of the prototype using software programs. Further, any differences in functionality may also be compensated using software models, multimedia interactive tools, virtual reality tools, mixed reality tools or augmented reality tools. In one embodiment, the small tech device or structure created by fabrication module 101 is made over an area greater than or equal to 1 mm². In one embodiment, the small tech device or structure created by fabrication module 101 is made over a volume greater than or equal to 1 mm³. In one embodiment, the small tech process is carried out over an area greater than or equal to 1 mm² or volume greater than or equal to 1 mm³. In one embodiment, a property of the created small tech device, structure or process is within 25% of expected values. In one embodiment, a property of a constituent of STES 100 is intentionally varied with a 10% tolerance. In one embodiment, the dimension of the created small tech device or structure is between approximately 0.5 μm-0.5 mm. In another embodiment, the dimension of the created small tech device or structure is less than 0.5 μm.

STES 100 further includes a metrology module 102 that may enable measurement of one or more physical, chemical or biological properties of a fabricated small tech device or structure with MFFS in the small tech regime. Furthermore, metrology module 102 may enable characterization of one or more characteristics of small tech processes. Additionally, metrology module 102 may allow for measuring, testing or characterizing a property of the created small tech device, structure or process, such as an electrical measurement, an optical measurement, a thermal measurement, a chemical property measurement, an optical microscopy measurement and/or an atomic force microscopy measurement. Additionally, metrology module 102 may enable quantification of uncertainty in the above measurement and characterization. In one embodiment, data for metrology module 102 may be automatically uploaded to the cloud via network 108 (discussed below) to perform validation against a set of expected results measured independently. In one embodiment, validation is performed by comparing the set of expected results that are obtained from validated models or from tests carried out in a factor or using a medium (e.g., storage device, online portal). In another embodiment, validation is performed by comparing the set of expected results obtained from tests carried out in a factory. In another embodiment, validation is performed using a medium, such as a storage device or an online portal. In one embodiment, metrology module 102 is equipped to measure properties of the created small tech device or structure, such as voltage, current, optical spectrum and temperature. In one embodiment, metrology module 102 is equipped to measure properties of the created small tech device or structure, such as optical, physical, chemical, biological, electrical, mechanical, magnetic, stoichiometric and thermal. In one embodiment, metrology module 102 is a stand-alone module or integrated with a data input/output interface to upload data to a mobile computing device (e.g., smartphone) or to a communication device to upload data to the cloud via a network (e.g., network 108 as discussed below). In one embodiment, metrology module 102 is connected to a computer to enable further processing of the measured data, where such further processing includes graphical representation, optimization, filtering, extrapolation, etc. In one embodiment, metrology module 102 may be further enabled to optimize the functionality of a prototype tool through the measurement of the parameters of the tool or process executed using the prototype or device fabricated using the prototype tool.

Furthermore, STES 100 includes a quality control module 103 that, along with a reporting and communication sub-module 104 (also referred to as a calibration module 104), that may enable calibration of data from metrology module 102 for referencing, where calibration can be done locally via calibration software stored in a memory 105 and executed by a processor 106. Alternatively, calibration may be performed externally by an external computing system 107 via a network 108 (e.g., Internet) connected to STES 100. In one embodiment, calibration module 104 is configured to calibrate the set of expected results. In one embodiment, calibration module 104 automatically logs and records evidence of execution of an experiment, or observation of multimedia tutorial, or participation in an interactive tutorial. In one embodiment, STES 100 or a module therein is associated with a unique identifier to facilitate validation using calibration module 104. In one embodiment, quality control module 103 includes a self-evaluation, a peer-to-peer evaluation or an instructor evaluation. In one embodiment, quality control module 103 operates automatically except in the case where an error between the measured data and the expected data exceeds a threshold, or in the case where the instructor may wish to review the measured data manually. In one embodiment, quality control module 103 contains substantially identical reference samples to provide for accurate calibration of measured results. In one embodiment, quality control module 103 is evaluated using a combination of automated and manual evaluation procedures.

The procedure of an exemplar quality control module 103 which addresses situations where the error between the measured data and the expected data exceeds a threshold requiring manual intervention is now discussed. In the first step, an assignment, with one or more questions, having one or more question types is submitted on an online platform, such as Canvas. Then, data from the submission is sent to a server using software programs based on JavaScript, Cascading Style Sheets (CSS), etc. These software programs may be integrated with the online platform and enable automatic grading to first filter out the answers that are substantially correct. In a third step, a utility file is run, which converts data from the submission that is related to partially or substantially incorrect answers into an editable, or automatically processable format. This conversion may additionally allow aggregation of all partially or substantially incorrect answers from one or more submissions in a substantially single file. In a fourth step, the substantially or partially incorrect answers are graded manually by an instructor, or automatically by a software program designed towards recognition of handwriting, patterns, keywords, etc., to give partial credit based on a defined configuration file. In a fifth step, the graded file can be uploaded to the server. Next, the grades on the online platform can be updated with information from this graded file, and finally released.

Additionally, quality control module 103 may enable validation of data from metrology module 102 against computational models, where the models may be available locally as a software tool (e.g., stored in memory 105), or through another medium, such as network 108, from external system 107. In one embodiment, validation is performed using a medium (e.g., storage device, online portal). In one embodiment, the software tool(s) stored in memory 105 may include a validated model, a virtual reality model, a simulation model, data analysis, data input/output and a communication interface.

Furthermore, quality control module 103 may enable validation of data from metrology module 102 against expected results, where the expected results measured independently are accessed through a medium, such as network 108, from external system 107 based on the unique identifier. The correctness of a result could be automatically assumed if, for example, the value of data from metrology module 102 is “clearly correct” based on a well-defined error range (e.g., within 25% error from the expected value). The incorrectness of a result could be automatically assumed if, for example, the value of data from metrology module 102 is “clearly incorrect” based on an error being significantly higher than a well-defined error range (e.g., >50% error with respected to expected value). If the data from metrology module 102 is worse than the expected value but the error is not too high (e.g., has an error between 25% and 50%), then the accuracy of the result may require manual intervention from an expert, such as an instructor.

In addition to the above three features, STES 100 may also optionally include a design/exploration module 109 that may enable parametric variation of small tech device or structure properties for design of experiments (DOE) to understand phenomenological trends, and to enhance or refine the quality of computational models. Furthermore, design/exploration module 109 may enable virtual exploration of small tech phenomena based on validated computational models. Design/exploration module 109 may also enable aggregation of results from multiple STESs to explore a DOE across the multiple STESs. Further, design/exploration module 109 may also include a virtual model of a device, process, tool or functionality to enable further design and exploration of experimental results. In one embodiment, quality control module 103 can enable optimization of the design and assembly of a prototype tool for enabling all the functionalities or a subset of functionalities that are typically present in a larger-scale tool (e.g., master tool) used in a small tech factory. Any difference in functionality may be compensated through software models and interactive tools, such as multimedia, virtual reality, augmented reality, mixed reality, etc.

In addition to the above, the scalability of deploying STES 100 is also an important characteristic for it to address the challenge of broad access. This can be achieved in the following ways, all of which form important concepts behind the present invention. For example, the ability for anybody to safely conduct the use of the system of the present invention in a residential setting or even in the absence of basic K-12 laboratory facilities. Furthermore, the system of the present invention is portable. Additionally, there is the ability to mass produce the system of the present invention while also, optionally, customizing constituents of fabrication module 101. Mass production and deployment of the same system with the same constituents may be the basic product, but for the purpose of education and innovation, customization or randomization of the characteristics of one or more constituents may be preferred, especially in a structured class environment, or for prototyping. Furthermore, there is the ability to associate each STES 100 with a unique identifier to enable calibration and validation of experimental results, especially with customized/randomized constituents.

STES 100 may also involve the design and assembly of prototypes of tools that are typically used in small tech factories for execution of small tech processes or for fabrication, measurement or characterization of small tech features or devices. As previously discussed, given the strict requirements for scaling and contamination, many of these tools are larger than human-scale, and highly complex. On many occasions, the complexity is a result of the associated requirements of the process, such as tight contamination control, rather than the core process itself. Precluding the need to include these associated requirements may potentially simplify the architecture of the tool and make it possible for a prototype of the tool to be developed for the purpose of a STES. Such a prototype (designed and assembled by STES 100) may retain a substantially similar subset of functionalities present in the “master” tool used in a small tech factory. Such a STES may allow the exploration of tool design and assembly for small tech processes and can be further augmented with an optimization framework to maximize the similarity in the functionality between the prototype and the master, given the constraints of portability, household safety, etc. for STES. For example, the subset of functionalities may be optimized for household safety, portability, performance, etc. Any substantial differences in functionality between the prototype and the master tool may be compensated by software models and interactive tools, such as virtual reality, mixed reality, augmented reality, etc. Through the design/exploration module, it may also be possible to change tool design and assembly parameters to understand the corresponding influence in functionality and then optimize for the same.

The perceived lack of broad access in small tech education can be overcome if the primary challenge of access can be addressed. This can be done by exposing more people to small tech, not by bringing them to small tech, but by taking small tech to them. The solution is the development of the system (STES) 100 of the present invention, which allows practical, hands-on exposure to fabricating, characterizing/measuring, validating and perhaps designing small tech structures or devices. Simultaneously, the use of such portable small tech labs should not compromise the broad objectives of engineering laboratory education. System 100 of the present invention can cover the broad spectrum of STEM disciplines amenable to small tech interventions. As opposed to only a limited exploration of the small tech space or a “mock” presentation of small tech through “macro”-technology proxies, system 100 of the present invention enables hands-on experiences with MFFS truly at the small tech scales. A key part of the experience will be a module for calibrating and validating the end result of the hands-on experiences through network 108 with the help of a unique identifier for each system. The design of a STES can be done with the objectives of traditional lab education in mind, thereby bringing it closer to real-world “brick-and-mortar” labs in terms of learning outcomes. That is, STES 100 is designed with a set of learning outcome objectives that are substantially similar to those in traditional engineering laboratories. Any differences in learning outcome objectives can be compensated by interactive tools, such as virtual reality, augmented reality, mixed reality, multimedia, video tutorials, etc. as discussed further below. For example, any objectives that are not achieved, because of the primary constraints of portability or household safety, can potentially be compensated through interactive tools, such as virtual reality, multimedia, augmented reality, mixed reality, etc.

The practice of small tech essentially involves fabrication of relevant structures or devices resulting from one or more of such structures, as well as the associated testing and characterization. System 100 of the present invention is deployable in a portable form factor not larger or heavier than a typical airline carry-on bag (for example, a box less than 50 inches in sum of all three dimension and weighing about 25 lb. or less), and which can be used in a residential setting with only basic protective equipment, such as gloves and goggles.

As has been discussed earlier, typically, these small tech materials and devices may be fabricated and tested in expensive labs, or cleanroom environments with expensive tooling and materials. This is because both fabrication and metrology of such structures places some unique constraints on issues, such as contamination control, substrate handling, etc. As an example, the state-of-the-art photolithography tools used in the semiconductor industry to fabricate some of the most advanced circuits can fabricate features smaller than 25 nm. This is several orders of magnitude smaller than a random dust particle that exists in the environment. Hence, the fabrication and metrology environments for these devices need to be extremely clean themselves and not be a source of further particulate contamination. In the same vein, there are several other issues that necessitate the use of such infrastructure for yield in small tech fabrication. One of the key concepts of the solution of the present invention is to minimize the negative influence of issues, such as particulate contamination, by designing the experimental methodology as well as the physical setup around these constraints, without compromising the ability to make and test small tech structures and devices. As an example, the process of nanoimprint lithography is considered. The process uses a semi-rigid master template with nanoscale features to transfer them onto a polymer film, almost like an embossing step. The semi-rigid nature of the template is desirable for certain aspects of the process, including pattern alignment and registration, but it can exacerbate the negative influence of a particle between the template and the substrate. A highly flexible, near conformable template, on the other hand, suffers from poor alignment accuracy but can confine the effects of particle contamination locally. Both template formats can lead to nanoscale pattern transfer over cm-scale areas. Hence, in a nanoimprint lithography experiment which is part of the education kit of the present invention, it can be beneficial to realize the process using a conformable template for a small tech device or structure. The device or structure may be designed in a way which does not require multiple patterning steps, thus precluding the need for precise patterning alignment. In another example, the process of spin-coating can be considered. This common process is typically carried out in a clean environment for depositing uniform films of a wide variety of materials on substrates. However, as part of an experiment, a stand-alone spin-coater can also be built using off-the-shelf components, such as a small motor, to deposit films of a given material. The difference here would be that the hands-on experiment may not have the same uniformity or defect-free coating profile that a proper cleanroom environment spin-coater might. Nevertheless, films with thicknesses even in the sub-micrometer and sub-100 nanometer regime can still be obtained in the experimental spin-coater through judicious choice of material properties, and through process approaches discussed below.

Another challenge lies in the actual process of making these small tech structures and devices. The ability to make features at such scales often requires a complex suite of tools that may not be amenable to downscaling to a hands-on kit. However, important aspects of the fabrication processes can be re-designed to use pre-fabricated constituents for successful execution of the process. Some of these constituents may have features at relevant small tech scales and can be pre-fabricated in a proper facility that has the capability to both make as well as test their properties with high accuracy and precision. The process may also use a combination of functional and non-functional materials (described below) to achieve this goal. As an example, in a spin-coating experiment, a process constituent may include a polymer solution that has been meticulously filtered and bottled in a cleanroom environment. Moreover, properties of these constituents can also be customized or randomized to render controlled variation in the expected results. In the same spin-coating experiment, for example, the concentration of solvent in the polymer solution can be changed in a controlled manner to allow for variation in the spin-coated thickness. Steps to address particles and contamination control to allow useful experimentation can include pure materials (substantially free of particles and contamination), clean wafers and templates, clean equipment components, etc. prepared and packaged in a small tech factory that leverages economies of scale to make this cost-effective, use of small-scale “clean boxes” with air flow protocols that minimize room contamination for a period of time as the experiments are set-up and conducted, and use of light scattering to inspect for and avoid particle contamination during experimentation.

After fabricating these structures, materials and devices, it is important to measure, test and validate the properties of the same. This can be done with the help of both off-the-shelf compact instruments, as well as custom-built measurement modules. Both off-the-shelf and custom modules may be physically assembled into a single stand-alone metrology module 102 with the ability to place and locate the test sample as well as a way to select the appropriate test among a suite of possible measurements. This suite can include a spectrometer for measuring optical properties, a multimeter for measuring electrical properties, a thermocouple for measuring thermal properties, etc. As an example, the optical properties of a spin-coated film may be used to determine the thickness of the film by using a built-in spectrometer present in metrology module 102. It is expected that the thickness measurements, for example, will not be as precise or accurate as high-end metrology tools, but, nevertheless it will still be possible to realize and test small tech phenomena to a reasonable degree of accuracy.

Another important aspect in system 100 is the ability to validate the measured properties of small tech structures, materials or devices. This validation can be done by first identifying the constituents of fabrication module 101 through a unique identification mechanism, such as a bar code, QR code, etc. This would provide a calibrated or expected set of results based on prior testing at a small tech facility, validated models that describe the relevant phenomena, or both. A reporting and communication module/calibration module 104 can be used to transfer information through a medium, such as network 108. For deployment of these systems in areas where access to such media might be limited, the calibrated results may also be provided as part of the system on a device, such as a USB stick, CD, etc., again, based on the unique identifier of the system.

Embodiments of metrology module 102 can include the use of a suite of tools with a portable and compact form factor for the ability to test, measure and characterize various properties of the fabricated small tech structures, materials and devices. Some of these tools can include a spectrometer (e.g., smartphone mountable spectrometer), optical microscope (e.g., XFox Mobile Phone Microscope, KingMas Clip-on Microscope), portable atomic force microscope (e.g., products sold by ICSPI Corp.), voltage and current sensors (e.g., PASPort), thermometer (e.g., PASCO wireless), etc.

The materials used in these experiments may be classified as functional or non-functional depending on whether they exhibit special photonic, magnetic, electronic, biological or chemical properties by virtue of some small tech characteristic and that benefit an end application tied to the same characteristic. Some examples of functional materials include: nanostructured materials that have special optical properties, such as negative index of refraction upon interaction with light; nanostructured materials that have certain biological properties such as anti-fouling; nanomaterials with special electrical and thermal properties such as graphene; nanomaterials with magnetic properties such as iron oxide nanoparticle dispersions, etc. Non-functional materials, on the other hand, do not exhibit these special properties, but can help facilitate small tech phenomena upon proper execution of the experiment. For example, spin-coating a non-functional material film can help explain how the reflected color of the film changes with film thickness, which can be a nanoscale optical thin film interference phenomenon. However, the material of this film may not have any other inherent characteristic. On the other hand, if a functional film, such as an organic semiconducting or conducting polymer were to be deposited, its thickness would not only drive the color of the film, but also its electrical properties.

Furthermore, it is important to maintain material safety. Small tech cleanroom environments are generally designed around user safety through proper protective equipment for handling of hazardous materials and constant exhaust of air in areas with harmful chemicals. For deploying a small tech system in a portable form factor, exposure to toxic materials can be substantially minimized by choosing materials that are considered safe to handle, store and dispose in a residential setting. At the same time, the systems can also be equipped with necessary personal protective equipment, such as gloves and goggles, with proper instructions on how to handle, store and dispose the chemicals that are needed to execute any experiment. In one embodiment, the only necessary personal protective equipment are gloves and goggles.

While the present invention allows small tech to be practiced hands-on, there are several benefits to the simultaneous use of software and virtual interaction as a complement to the hands-on experience. Software implies off-the-shelf packages, custom-built programs, interactive content, etc. which may be stored in memory 105. The use of software can help on multiple fronts. First, software can help in parametric design exploration through the use of validated models. A single experiment (or a series of experiments with controlled variation of parameters) generally provides a limited number of data points in a combinatorial design of experiments. The small tech experiments in the deployed STES 100 may also not be exhaustive enough to allow exploration of the complete design space. A software tool can complement this by first using the results of the few hands-on experiments to validate a computational software model, and then allowing virtual variation of parameters in software to assess the influence on expected experimental outcome. For example, the color or spectrum obtained on a spin-coated film can be correlated against an expected thickness value, based on a software tool that uses the material properties (e.g., refractive index and extinction coefficient) expected spectral properties based on thin film interference computational models. Since it may be difficult to coat multiple films on different substrates due to physical constraints associated with the portable system, software tools can allow a variation of film thickness and material properties to see how color or spectra might change with the film thickness. Secondly, software tools can be extremely powerful for metrology and characterization. They can not only help in validation of results, as explained earlier, but also for minimizing noise in the measured properties. This is particularly true if metrology module 102 relies on sensitive data measurements for explanation of experimental results. For example, current and voltage measurements realized from nanostructured transistors can be extremely small, which would need a high resolution multimeter, which can also be sensitive to noise. However, with appropriate filtering of data, through multiple measurements for example, statistical analyses can be conducted in software tools to minimize the noise and improve the signal to noise ratio for such measurements. Thirdly, software can also be a valuable resource in training and demonstrating some key concepts behind the experiments, through tutorials, videos, virtual tools or process explorations, virtual reality exploration of tools or process environments, etc. Fourthly, software also provides a key interface for the reporting and communication involved in calibration module 104. The measured properties can be logged, analyzed, calibrated and validated with the help of software tools. It can also allow for data input/output, transfer to network 108, as well as peer-peer or instructor interaction when deployed in an educational setting.

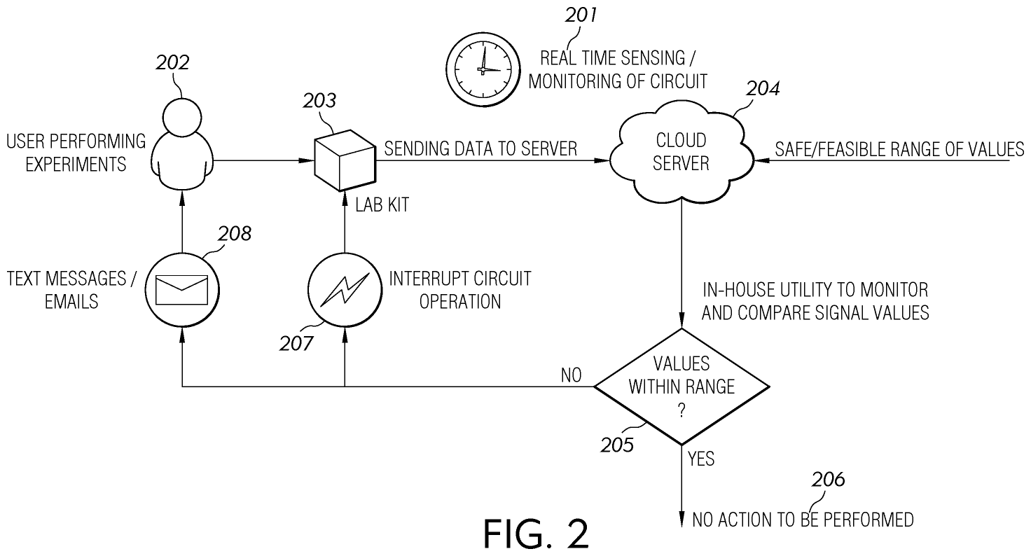

Data from multiple STESs can also be aggregated to perform one or more Design of Experiments (DOEs). The calibration or reporting module 104 may also include a real-time sensor that detects changes in experimental conditions or parameters and automatically logs them in the cloud using network 108. This can enable the instructor to validate whether the experiment was performed correctly. In addition, there may be a “fuse” switch which may remotely disable the experiment if one or more signals fall outside a safe feasible range, as determined by prior testing in the factory or from manufacturer provided information. The sensor can send this data to the cloud/server where based on the values, interrupt or action signals can be generated and sent to fuse switches in the circuit to stop the operation. Also, automated text messages can be sent to the user explaining the reason why the experiment was stopped. A software utility program can be created to perform this operation. An exemplar methodology/flow of this approach is shown in FIG. 2. FIG. 2 is a diagram of the sensing and safety control methodology for hand-held lab kits in accordance with an embodiment of the present invention.

Referring now to FIG. 2, in conjunction with FIG. 1, a real-time speed sensor 201 can be attached to a spin-coating motor, which is connected to reporting module 104, and which automatically logs the spin speeds of the motor, and corresponding time stamp, during execution of the experiment. Reporting module 104 may also include software that automatically provides evidence of observation of multimedia tutorials or videos linked with STES 100. These tutorials or videos may include instructions for carrying out the experiment in a safe manner, as well as explain the theoretical and practical concepts relevant to the experiment. These tutorials or videos may be provided with STES 100 on a medium such as a USB stick, CD-ROM, etc., or available online, or provided in a live interactive session with an instructor, teaching assistant or a domain expert. The objective is to ensure that students are not getting exposed to kit materials, gadgets, etc. unless they have read the instruction manual, passed the qualifier quizzes, or other pre-requisites established by the instructors. This can further be ensured by adding a physical or digital lock with an alphanumeric code which is unique to each STES by being linked with the unique identifier, and which is released upon successful completion of pre-requisites. In one embodiment, STES 100 is disabled via a network, a cloud control, a physical lock or a digital lock and is enabled only after a corresponding system completes procedural instructions or completes an assignment (e.g., quiz) demonstrating completion of said procedural instructions.

As shown in FIG. 2, as the user is performing experiments in step 202, data connected with the experiments is sent in step 203 to a sever 204 (e.g., cloud server) (e.g., external system 107). For example, a user's computing device may be connected to cloud server 204 via a network (e.g., wide area network) thereby enabling the data connected with the user's experiments to be sent to cloud server 204. In one embodiment, cloud server 204 receives the safe/feasible range of values associated with the experiment, such as from reporting/calibration module 104 via network 108. In one embodiment, cloud server 204 is connected to STES 100 via network 108. In one embodiment, an in-house utility program is configured to monitor and compare the signal values (e.g., the signal values obtained from the data associated with the experiments) to determine whether the values are within the designated range of values (the received range of values) in step 205. In one embodiment, such an in-house utility program is a software program running on cloud server 204. In another embodiment, such an in-house utility program is a software program running in calibration module 104. In such an embodiment, calibration module 104 receives the signal values obtained from the data associated with the experiments from cloud server 204. Furthermore, in such an embodiment, the safe/feasible range of values associated with the experiment may not need to be sent to cloud server 204 from reporting/calibration module 104.

Referring again to FIG. 2, if the values are within the designated range of values, then, in step 206, no action needs to be performed by the in-house utility program. If, however, the values are not within the designated range of values, then the circuit operation in the lab kit is interrupted in 207 (i.e., the execution of the experiment is disabled) by the in-house utility program and text messages/e-mails are sent to the user in 208, such as via network 108, by the in-house utility program regarding the values not being within the designated range of values.

There are various applications of STES 100, such as the following.

### Electronic:

Fabrication and testing of a semiconductor diode
Fabrication and testing of a transistor (e.g., a think film transistor)
Fabrication and testing of electrical properties of structured semiconducting materials, such as graphene ribbons
Fabrication and testing of organic semiconductor structures

### Photonic:

Fabrication and testing of wire-grid polarizers
Fabrication and testing of optical gratings
Fabrication and testing of metal mesh transparent conductors
Fabrication and testing of metamaterial structures
Fabrication and testing of light trapping structures for photovoltaic cells

### Optical:

Deposition and optical characterization of thin films
Microscopy and characterization (e.g., scattering) of particle contamination in liquids and gases
Detection of nanoparticle size through reflected or emitted spectra (e.g., gold nanoparticles)
Fabrication and testing of organic light emitting diodes

### Biological/Biomedical:

Fabrication of a selective biosensor
Fabrication and testing of anti-microbial/superhydrophobic structures
Fabrication and testing of Coulter counters for particle detection
Fabrication and testing of thermally responsive hydrogel structures
Characterization of functionalized nanoparticles

### Energy:

Fabrication of thin film solar cells or light trapping structures to increase the efficiency of solar cells
Fabrication of thin film and nanostructured ultra-capacitors
Fabrication of light management structures for increasing the efficiency of displays

Another feature of the present invention is the ability to customize one or more properties of the constituents in fabrication module 101 of the system. It is noted that some variation is natural, randomly occurring and beyond control. However, the aforementioned customization is controlled, thereby intentionally allowing properties to vary. An example of such controlled variation can be changing the weight percentage of nanoparticles in a dispersion, changing the feature dimensions on a photolithography mask or an imprint lithography template, modulating the maximum speed on a spin-coating motor, etc. If implemented within the same system, this variation can allow for an exploration of the parametric design space experimentally. If implemented across different systems, it can lead to a randomized set of STES 100 (with their respective unique identifiers), similar to a randomized question bank, which is useful when deployed in a structured classroom environment. Typically, the variation is introduced in the constituents that are pre-fabricated in small tech facilities with high degree of accuracy and precision, but the variation can also be implemented during the course of fabrication and testing within the same system. The systems can be coded with a unique identification mark to enable tracking and validation of measurement results. This randomization, when implemented in a large enough pool of systems, can potentially allow for enough information to be collected for a global experimental parametric exploration or design of experiment, thereby providing collective data with educational value for a large group of people.

In one embodiment of the present invention, STES 100 can comprise a partially fabricated device as part of the fabrication module 101. The experiment may involve completing the device to make it functional, or the experiment may involve conducting one or more small tech processes on the device. Students may be provided a substantially identical partially fabricated device, and the distribution of their results after completing the fabrication, metrology and calibration may be aggregated to provide a statistical analysis of the substantially similar devices. Students may also be provided substantially similar devices across different STESs, but the devices may be partially fabricated to different extents. Across multiple STESs, the goal might then be to complete different small tech processes or add different small tech structures to obtain either:
substantially similar completed devices among all the students after the experiments have been conducted. Or,
substantially similar incomplete devices at different stages of fabrication among all the students. In this case, the incomplete devices may be:
   circulated among students so that different fabrication or processing steps may be completed by different students to produce a finished device, or
   the incomplete devices may be completed in small tech factories, or
   the partial fabrication may involve making sub-components or sub-structures of a completed device, and those sub components or sub structures may be aggregated together to fabricate a completed device or structure.
      This can provide deep understanding of a class of small tech fabrication processes or structures to one student, and a different class of processes or structures to another student. When aggregated across multiple STESs, all students in the cohort may benefit from a broad understanding of multiple classes of small tech processes or structures that are necessary to form a fully functional device.

### Exemplar Embodiments

STES for Photolithography:

In this system, the constituents of fabrication module 101 can include flexible photomasks with 10-100 μm resolution, flexible PET sheet coated with 10-100 nm of copper and topped with 0.1-10 μm film of positive photoresist. A UV flashlight, a silicone slab mold and household-safe cleaning, etching and developing solutions can also be included along with an instruction manual, software tools and protective equipment, such as safety goggles and gloves. The photomask, PET sheet and household-safe chemical solutions can be pre-fabricated in a small tech facility to ensure good accuracy, precision and yield. The photomask patterns can include electronically relevant features, such as serpentines, inter-digitated electrodes and spaced electrodes containing contact pads. The fabricated patterns may be used to complete a small tech device, such as OFET (Organic Field Effect Transistor), sensor, metal mesh transparent conductor, etc., in other such systems. The photomask can be used to selectively expose the resist coating on the Cu-coated PET substrates using the UV flashlight maintained at a fixed height with the help of a pre-fabricated silicone slab. The photoresist can be later developed using the supplied household-safe chemicals and the exposed copper layer can then be etched away using household-safe chemical solutions. The photomask patterns, copper thickness and photoresist thickness can be customized across different systems and be associated with a unique identifier. Metrology module 102 can consist of a microscope that can be attached to a cell phone camera for measuring pattern dimensions, multimeter with an optional sheet resistance probe for measuring electrical properties, and spectrometer or photodiode for measuring optical properties. Calibration module 104 can gather the measured data and upload to the cloud over network 108. Here PET stands for Polyethylene terephthalate. The PET substrate thickness is about 7 mil (˜175 μm). A representative photoresist material is AZ5209E from EMD Performance Materials Corporation. A photoresist developer is MF26E from EMD Performance Materials Corporation. A copper etchant is a mixture of 3% H₂O₂ (hydrogen peroxide) and 5% acetic acid in water. A photoresist stripper is isopropylalcohol (IPA)

STES for Deposition of Thin Films:

In this system, the constituents of the fabrication module can allow construction of a prototype spin coater using a computer fan to get films ranging from ˜5 nm-5 um thick. The module can also include commercial electronic grade polished silicon wafers, plastic wafer and a water-based polymer solution, which is prepared in a clean small tech facility. The concentration of the polymer solution and maximum speed of the spin-coater can be controlled to ensure an accurate film thickness value. Metrology module 102 can consist of a spectrometer or camera for analyzing the color of the deposited film. The spectrometer can be assembled on a smartphone camera or similar device with a supplied optical grating and flashlight. Visual inspection of the film can be done to highlight the presence of defects due to particle contamination. The concentration of the polymer solution can be changed within the same system to coat a silicon wafer with a different film thickness resulting in a different color, and can be associated with a unique identifier. At the same time, a plastic wafer can also be coated to explain the presence or absence of color because of thin-film interference. Calibration module 104 can consist of a software simulator to validate the correlation of color with film thickness and materials properties. Furthermore, the color can also be validated by calibrating a camera image against a standard reference available in the cloud using image-processing techniques. Variability in the cameras from student to student may be accounted for automatically by including in calibration module 104, a substantially identical reference sample. Each student can take a picture or spectral measurement of the reference sample and upload that image to the cloud for further image-processing. In this system, an example of the water based polymer solution discussed above is 4% polyvinylalcohol (PVA) from Sigma Aldrich in water.

STES for Nanoimprint Lithography:

This system relies on some components given in the earlier embodiments and shows cross-compatibility of the constituents across different systems. Fabrication module 101 can consist of two conformable nanoimprint templates, a flexible substrate and a household-safe nanoimprint resist solution, all of which are pre-fabricated in a clean small tech facility. In one embodiment, the nanoimprint templates can have various patterns at MFFS scales ranging from 10 nm-1 μm that enable fabrication of a variety of devices, such as wire-grid polarizers, metal mesh, photonic crystals, transistors, etc. The templates can be placed face-up and the imprint resist dispensed on it. The substrate can be placed on top and the resist can then be cured using the UV flashlight from the photolithography system. The template and substrate can be manually separated to replicate the template pattern on the substrate. Metrology module 102 can include the spectrometer from the thin film deposition system, or a multimeter from the photolithography system, to capture optical and electrical information of the imprinted pattern. The pattern features and imprint resist properties can be changed for customization and be associated with a unique identifier. An intentionally high resolution pattern can also be used to demonstrate limits of the process and justify the need for sophisticated equipment and materials. For a one-dimensional pattern, such as lines and spaces, metrology module 102 can also include the use of a drop of water with an imaging system to capture the direction of alignment of the water drop (typically parallel to the direction of the lines). The measured results and images can be validated in calibration module 104 by uploading them over the cloud. In this system, the template and the substrate can be made of polycarbonate (PC), PET, etc.; or made of more rigid materials, such as glass, silicon, silicon carbide, etc. The imprint resist may be Poly(ethylene glycol) Di-Acrylate (PEGDA) The nanoimprint lithography STES can also be used for the fabrication of photonic or diffractive optical elements, such as Flat Lenses that can be used to demonstrate a variety of optical phenomena.

STES for Exploration of OLEDs

This STES has two parts. The first part involves obtaining a current vs. voltage curve (I-V curve) of a commercial LED while using a voltage source and a multimeter as part of metrology module 102. The students discuss the attributes of the LED I-V curve and compare it with theory in calibration module 104. The second part involves preparing an Organic LED (OLED). The benchmark procedure was based on available video lab manuals and procedures (video tutorials). Briefly, an indium tin oxide (ITO) substrate is coated with a ruthenium dye solution over a hot plate. The solvent is evaporated to leave a solid dye layer. Then, a liquid alloy of indium gallium is applied on the solid dye layer, using a cotton swab, such as a Q-tip, to form the anode. An important modification to this procedure was the use of an indium bismuth alloy foil, instead of the liquid indium-gallium alloy, or instead of a cadmium-containing metal alloy called “Wood's Metal.” The liquid indium-gallium alloy easily stains and is very difficult to handle in residential setup. Wood's Metal contains cadmium raising safety concerns. The indium bismuth foil has a higher melting point than the indium-gallium alloy, and can be applied on the designated area on top of the dye and melted on the hot plate. This setup is household-safe, as well as more reliable for connecting electrical lids to the finished OLED. The STES also includes a cup warmer to serve as a hot plate.

STES for Exploration of OFETs

The Organic Field Effect Transistor (OFET) STES has been designed to integrate equipment from other STES to fabricate a working OFET. The first part involves using metrology module 102 to obtain an I-V curve for a commercial Metal Oxide Semiconductor Field Effect Transistor (MOSFET) and compare its behavior with theory using calibration module 104. The second part is fabrication of an OFET. The students use the equipment from the photolithography STES to fabricate inter-digitated electrodes of copper on PET film. Then, they use the hot plate given in the OLED STES and an organic semiconductor solution (e.g., Lisicon® SP400-1775 from EMD Millipore) to form a coating on the electrodes. An organic dielectric solution of Polyvinyl Butyral from Sigma Aldrich® is used to form the dielectric layer. The dielectric film is coated using the spin coater which is included in the spin-coating STES. Then, the students use a Poly(3,4-ethylenedioxythiophene)-poly(styrenesulfonate) (PEDOT-PSS) solution from Sigma Aldrich® to form an organic gate electrode. An embodiment of the fabricated OFET is capable of providing approximately 30 uA when applying a driving voltage of 2V between the source and drain, and applying 1.5V of gate voltage. The fabricated OFETs have been shown to be stable for more than a month under ambient conditions. This fabrication procedure has been designed for a residential environment, using ambient conditions and without encapsulation, which is typically required in commercial OFETs because of problems with stability and/or toxicity.

STES for Exploration of DSSCs

This STES has two components. The first, is obtaining an I-V curve for a commercial solar cell, as part of metrology module 102, using a flashlight as the light source, and a potentiometer and a multimeter for measuring voltage and current. The students calculate the fill factor and learn about the attributes of the solar cell electrical behavior using calibration module 104. In the second part, the students fabricate a Dye Sensitized Solar Cell (DSSC) as an example for emerging concepts in light harvesting. The benchmark for the lab procedure has been based on literature, such as University of Wisconsin Lab Manual “Titanium Dioxide Raspberry Solar Cell.” An important modification to this lab procedure has been the use of ruthenium dye cis-Bis(isothiocyanato)bis(2,2′-bipyridyl-4,4′-di carboxylato)ruthenium(II) instead of raspberry juice. This allows the fabricated devices to be more stable, and have better performance without compromising the household safety of the STES.

STES for Exploration of Metal Mesh

This STES has been designed to introduce concepts relevant to transparent flexible conductors. The students use the equipment given previously in the photolithography STES with a photomask containing four mesh patterns. Students fabricate the mesh patterns on a copper coated Polyethylene terephthalate (PET) film. After processing and etching, the fine copper mesh patterns on the transparent PET are obtained. As part of calibration module 104, the students measure relative transparency by using their cellphone cameras and process the images using software, such as Image.J Geometric measurement of the pattern features is performed using a miniature microscope attached to a smart phone or a cellular phone camera. The students also get acquainted with optical moiré and diffraction patterns produced by the copper mesh and learn about optimizing the correct mesh structure to avoid these optical phenomena that prevent the film from being viable for display applications. The students also measure conductivities (or, equivalently, sheet resistances) of the metal mesh structures relevant for touchscreen applications. A design of the experiment project can be conducted by giving different mesh structures to each student. In addition, the students can gather optical and electrical data from each other, compare it and fit it into a model using calibration module 104.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A portable system comprising:
a fabrication module configured to enable creation of a small tech device or structure or to enable demonstration of a small tech process;
a metrology module configured to allow measuring, testing or characterizing a property of said small tech device, structure or process; and
a quality control module configured to validate results from said metrology module against a set of expected results measured independently;
wherein said portable system is used for a design and assembly of a prototype tool with all the functionalities or a subset of functionalities present in a master tool used in a small tech factory.

2. The portable system as recited in claim 1, wherein said subset of functionalities is optimized for one of the following: household safety, portability and performance.

3. The portable system as recited in claim 2, wherein a difference in functionalities between said prototype and said master tool is compensated by one of the following: software models and interactive tools.

4. The portable system as recited in claim 3, wherein said interactive tools comprise one of the following: virtual reality, mixed reality, and augmented reality.

5. The portable system as recited in claim 1, wherein said portable system is designed with a set of learning outcome objectives.

6. The portable system as recited in claim 5, wherein said set of learning outcome objectives is based on objectives used in engineering laboratories.

7. The portable system as recited in claim 6, wherein any differences between said set of learning outcome objectives and said objectives used in engineering laboratories are compensated by interactive tools.

8. The portable system as recited in claim 7, wherein said interactive tools comprise one of the following: virtual reality, augmented reality, mixed reality, multimedia and video tutorials.
